(19) United States
(12) Patent Application Publication
(10) Pub. No.: US 2007/0190711 A1
(43) Pub. Date: Aug. 16, 2007

(54) Semiconductor device and method for incorporating a halogen in a dielectric

(76) Inventors: Tien Ying Luo, Austin, TX (US); Olubunmi O. Adetutu, Austin, TX (US); Eric D. Luckowski, Round Rock, TX (US); Narayanan C. Ramani, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/351,517

(22) Filed: Feb. 10, 2006

(51) Int. Cl. H01L 21/8234; H01L 21/336; H01L 21/3205

(52) U.S. Cl. 438/197; 438/305; 438/585; 438/591

(57) ABSTRACT

A method of forming a semiconductor device, the method includes forming a gate dielectric over the semiconductor substrate, exposing the gate dielectric to a halogen, and incorporating the halogen into the gate dielectric. In one embodiment, the halogen is fluorine. In one embodiment, the gate dielectric is also exposed to nitrogen and the nitrogen is incorporated into the gate dielectric. In one embodiment, the gate dielectric is a metal oxide.

### RELATED APPLICATIONS

This is related to U.S. patent application Ser. No. 10/969,486 filed Oct. 22, 2004, entitled “Plasma Impurification of a Metal Gate in a Semiconductor Fabrication Process”, and assigned to the current assignee hereof.

This is related to U.S. patent application Ser. No. 10/687,271 filed Oct. 16, 2003, entitled “Multi-Layer Dielectric Containing Diffusion Barrier Material”, and assigned to the current assignee hereof.

This is related to U.S. patent application Ser. No. 11/067,257 filed Feb. 25, 2005, entitled “Method of Making a Nitrided Gate Dielectric”, and assigned to the current assignee hereof.

This is related to U.S. patent application Ser. No. 11/146,826 filed Jun. 7, 2005, entitled “In-Situ Nitridation of High-K Dielectrics”, and assigned to the current assignee hereof.

### FIELD OF THE INVENTION

The present invention relates to semiconductor devices, and more particularly, to a semiconductor device and method for incorporating a halogen in a dielectric.

### RELATED ART

In processes for forming semiconductor devices, it has been common to form the gate dielectric using silicon dioxide. In order to prevent degradation of the electrical properties of the semiconductor device, it was generally undesirable to reduce the dielectric constant of the gate dielectric. Fluorine reduces the dielectric constant (K) of silicon dioxide, and thus it was not desirable to use fluorine in the gate dielectric.

### BRIEF DESCRIPTION OF THE DRAWINGS

The present invention is illustrated by way of example and not limited by the accompanying figures, in which like references indicate similar elements, and in which:

FIGS. 1-4 illustrate, in a cross-sectional view, a portion of a device in accordance with one embodiment of the present invention;

FIG. 5 illustrates, in flow diagram form, a process for forming a semiconductor device in accordance with one embodiment of the present invention; and

FIGS. 6-7 illustrate, in a cross-sectional view, a portion of a device in accordance with an alternate embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

It is now becoming more common to use a high-K dielectric for a gate dielectric. One reason for this is that thicker films of high-K materials (e.g. metal oxides) can be used as the gate dielectric without significantly degrading the electrical properties of the semiconductor device. As used herein, the term “high-K materials” refers to materials that have a dielectric constant higher than the dielectric constant of silicon dioxide.

It has been found that using a halogen, such as, for example fluorine, in the gate dielectric of a semiconductor device improves the electrical properties of the semiconductor device. One way that the electrical properties of a semiconductor device may be improved is by improving the mobility of holes and electrons. Providing a halogen at the interface between the gate dielectric and the semiconductor substrate passivates the interface (e.g. reducing dangling bonds) so that the mobility of the holes and electrons through the gate channel formed in the semiconductor is improved. A second way that the electrical properties of a semiconductor device may be improved is by improving the reliability (e.g. endurance) of the semiconductor device. It has been discovered that providing a halogen in the gate dielectric between the gate dielectric and the semiconductor substrate improves the reliability of the semiconductor device.

Providing nitrogen in the gate dielectric has several advantages, including increasing the dielectric constant (K) so that future scaling of the gate dielectric may be done more easily as the dimensions used in semiconductor devices are reduced for future technology. In addition, nitrogen in the gate dielectric may improve the gate dielectric film quality, and hence the reliability of the semiconductor device. Also, nitrogen in the gate dielectric may prevent out-gassing of a halogen that has been incorporated in the gate dielectric.

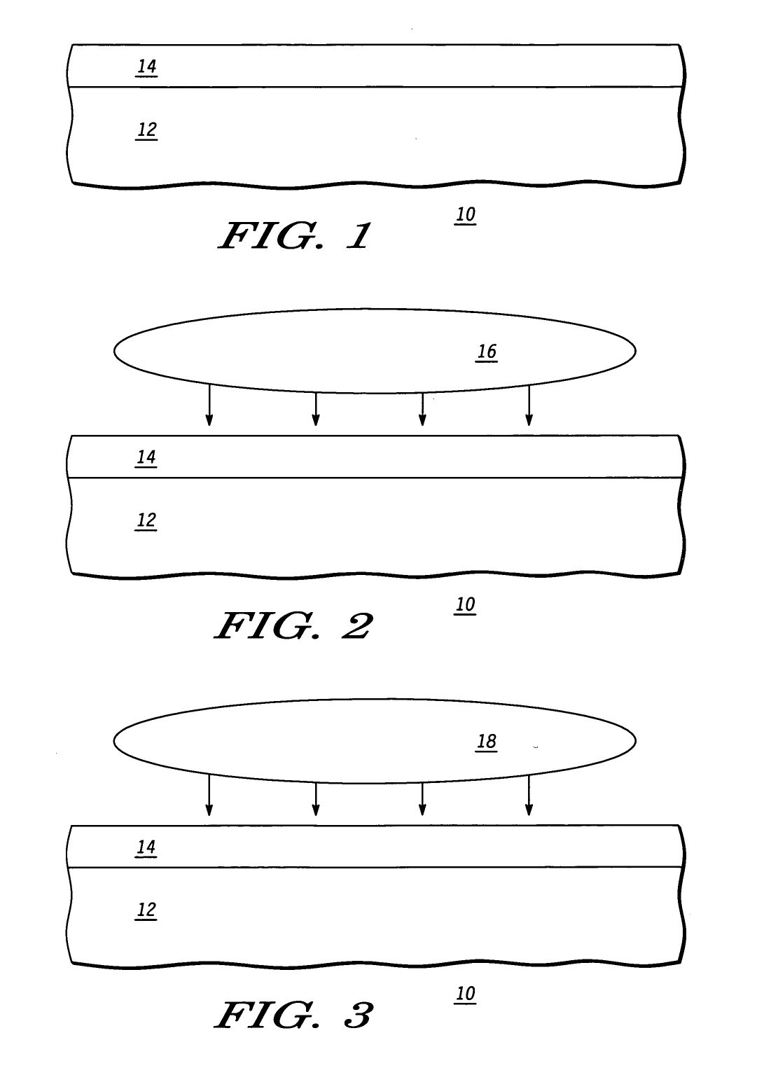

FIG. 1 illustrates a cross-section of a portion of one embodiment of device 10. Device 10 includes a gate dielectric 14 that is formed overlying semiconductor substrate 12. Substrate 12 may be formed of any semiconductor material, such as, for example, silicon, gallium arsenide, silicon germanium, germanium, etc. Alternately, substrate 12 may be a semiconductor on insulator (SOI) substrate. In one embodiment, gate dielectric 14 may be a high-K dielectric. Some examples of high-K dielectrics that may be used are oxides, nitrides, silicates, or aluminates of metals such as hafnium, zirconium, titanium, tantalum, or any combination thereof. Alternate embodiments may use any desired dielectric material or materials for the gate dielectric. Alternate embodiments may use an oxide of any semiconductor material, such as, for example, silicon dioxide, as the gate dielectric. Gate dielectric may be formed using any desired process, such as, for example, chemical vapor deposition. (CVD), atomic layer deposition (ALD), physical vapor deposition (PVD), or plasma enhanced CVD (PECVD). However, alternate embodiments may use a different process or combination of processes to form the gate dielectric layer.

In FIG. 2, the gate dielectric 14 is exposed to a plasma 16. In one embodiment, plasma 16 includes one or more halogens, such as, for example, fluorine, chlorine, bromine, iodine, and astatine. Note that plasma 16 may include other materials, such as, for example, argon and/or helium, which may be used to aid in the forming and/or stabilizing of the plasma 16. In addition, plasma 16 may include other materials that are used for other purposes. In one embodiment, the chuck temperature may be used in the range of room temperature (approximately 25 degrees Celsius) to 700 degrees Celsius. In an alternate embodiment, the chuck temperature may be used in the range of room temperature (approximately 25 degrees Celsius) to 80 degrees Celsius. In yet another embodiment, the chuck temperature may be approximately 55 degrees Celsius. In one embodiment, the chamber pressure may be in the range of 0.005-1.0 Torr. In an alternate embodiment, the chamber pressure may be in the range of 0.005-0.050 Torr. In yet another embodiment, the chamber pressure may be approximately 0.010 Torr. In one embodiment, plasma 16 may also include a nitrogen containing material.

In one embodiment, plasma 16 may comprise one or more of tetrafluoromethane CF₄, sulfur hexafluoride SF₆, nitrogen trifluoride NF₃, difluoromethane CH₂F₂, octafluorocyclobutane C₄F₈, trifluoromethane CHF₃, and methyl fluoride CH₃F. Alternate embodiments may have different gases.

Note that the halogen incorporated into the gate dielectric 14 does not act as a dopant in gate dielectric 14. The halogen does not act as a dopant because the halogen does not contribute conduction electrons to the current in the channel formed underlying the gate dielectric 14 when device 10 is conducting.

In FIG. 3, the gate dielectric 14 is exposed to a plasma 18. In one embodiment, plasma 18 includes a nitrogen containing material, such as, for example, ammonia, nitrogen, nitric oxide, nitrous oxide, or nitrogen trifluoride, or any appropriate combination thereof. Note that plasma 18 may include other materials, such as, for example, argon and/or helium, which may be used to aid in the forming and/or stabilizing of the plasma 18. In addition, plasma 18 may include other materials that are used for other purposes. Note that if the plasma 16 from FIG. 2 includes a nitrogen containing material, some embodiments will not require the additional plasma exposure illustrated in FIG. 3. Note that standard processes may be used to form and provide the plasmas 16 and 18 illustrated in FIG. 2-3. Note that the temperatures and pressures used may be the same as or similar to the ones described above FIG. 2. However, alternate embodiments may use different temperatures and pressures.

In one embodiment, if gate dielectric 14 comprises a metal oxide, the halogen in plasma 16 (see FIG. 2) may be incorporated into the gate dielectric 14 before or approximately concurrent with the incorporate of nitrogen (see FIG. 3). If the incorporation of the halogen and the nitrogen are performed approximately concurrently, the plasma 16 may include both the halogen and the nitrogen and the step illustrated in FIG. 3 is not required. In one embodiment, at least a portion of the exposing of the gate dielectric 14 to a plasma comprising nitrogen occurs concurrently with at least a portion of the exposing of the gate dielectric 14 to a plasma comprising a halogen.

In an alternate embodiment, if gate dielectric 14 comprises silicon dioxide, the halogen in plasma 16 (see FIG. 2) may be incorporated into the gate dielectric 14 before, after, or approximately concurrent with the incorporate of nitrogen (see FIG. 3). If the incorporation of the halogen and the nitrogen are performed approximately concurrently, the plasma 16 may include both the halogen and the nitrogen and the step illustrated in FIG. 3 is not required. Alternately, if gate dielectric 14 comprises silicon dioxide, the plasma treatment illustrated in FIG. 3 may be performed before the plasma treatment illustrated in FIG. 2.

Note that the incorporation of the halogen and nitrogen, regardless of the order in which they are incorporated, may be performed in situ without breaking vacuum. In alternate embodiments, vacuum may be broken between the incorporation of the halogen and nitrogen, and thus different chambers may be used. Note that if instead of plasma treatment, direct. implantation of the halogen (FIG. 2) or nitrogen (FIG. 3) into the gate dielectric 14 is performed, some damage to the surface region of the gate dielectric 14 may result. Such surface damage to gate dielectric 14 may degrade the reliability and electrical performance of device 10.

In FIG. 4, a gate electrode 20 is formed overlying gate dielectric 14. Gate electrode 20 may comprise one or more metal containing materials, such as, for example, tantalum carbide, tantalum silicon nitride, tantalum nitride, tungsten nitride, tungsten, iridium, iridium oxide, iridium nitride, ruthenium, ruthenium oxide, ruthenium nitride, molybdenum oxide, molybdenum nitride, aluminum nitride, and silicon, or any combination thereof. Alternate embodiments may use any desired material or materials for gate electrode 20. In some embodiments, gate electrode 20 may comprise a plurality of layers formed using the materials listed above and as well as other appropriate conductive and non-conductive materials, such as, for example, tungsten, silicon, silicon nitride, and metal silicide. In the illustrated embodiment, non-conductive dielectric spacers 24 are formed adjacent to the gate dielectric 14 and the gate electrode 20. In alternate embodiments, a thin oxide (not shown) may be interposed between spacers 24 and gate electrode 20. Alternate embodiments may not use spacers 24. In the illustrated embodiment, current electrode regions 22 are formed in semiconductor substrate 12. These current electrode regions 22 may be formed in any desired and known manner. If desired, further processing may be performed to complete device 10 in any desired manner.

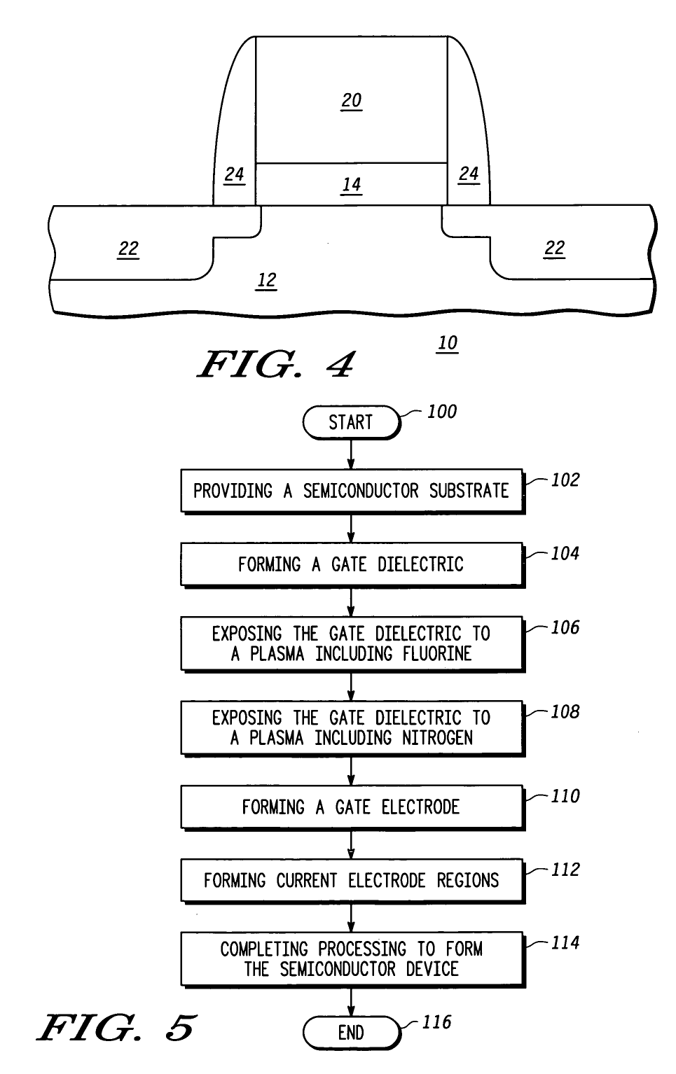

FIG. 5 illustrates, in flow diagram form, a process for forming a semiconductor device (e.g. device 10) in accordance with one embodiment. The flow starts at oval 100. The flow then proceeds to block 102 where the step of providing a semiconductor substrate is performed. From step 102, the flow proceeds to block 104 where the step of forming a gate dielectric is performed. From step 104, the flow proceeds to block 106 where the step of exposing the gate dielectric to a plasma including fluorine is performed. From step 106, the flow proceeds to block 108 where the step of exposing the gate dielectric to a plasma including nitrogen is performed. From step 108, the flow proceeds to block 110 where the step of forming a gate electrode is performed. From step 110, the flow proceeds to block 112 where the step of forming a current electrode regions is performed. From step 112, the flow proceeds to block 114 where the step of completing processing to form the semiconductor device is performed. From step 114, the flow proceeds to oval 116 where the process ends. Note that when the gate dielectric is exposed to the fluorine, the fluorine is incorporated into the gate dielectric. Note that when the gate dielectric is exposed to the nitrogen, the nitrogen is incorporated into the gate dielectric. This may have the effect of stuffing the grain boundaries of the gate dielectric with nitrogen so that out-gassing of the halogen is reduced significantly during subsequent high temperature processing.

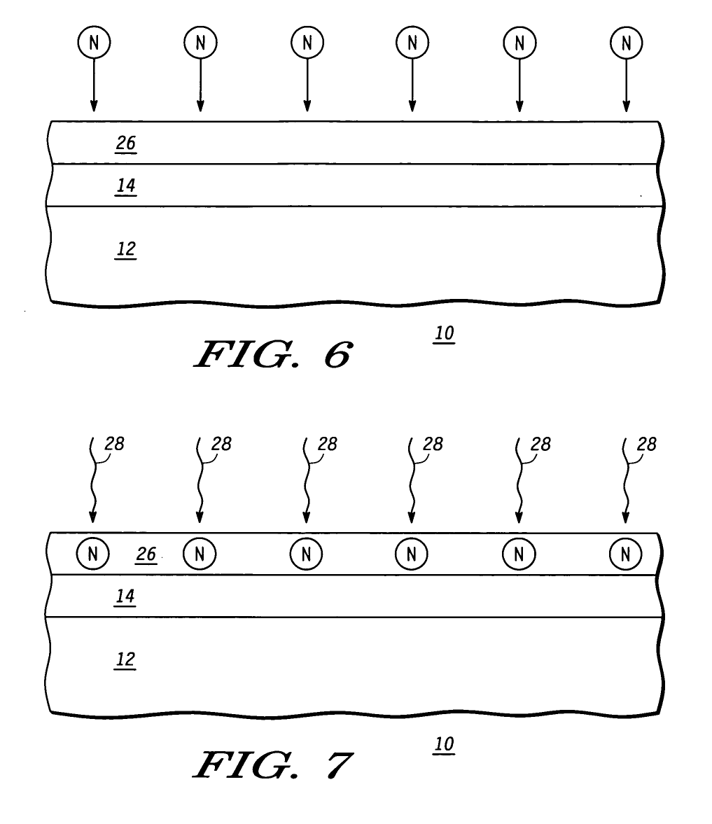

FIGS. 6-7 illustrate an alternate embodiment for forming a portion of device 10. Starting from the device 10 of FIG. 2 after the halogen has been incorporated, an implant layer 26 is formed overlying gate dielectric 14. FIG. 6 illustrates nitrogen being implanted into implant layer 26. Implant layer 26 may be a sacrificial layer that is subsequently removed, or implant layer 26 may be a portion of gate electrode 20 (see FIG. 4). Any desired angle of implant may be used. In one embodiment, a zero degrees implant is used. In one embodiment, implant doses and energies may be used that produce concentrations of nitrogen in gate dielectric 14 greater than two atomic percent. In one embodiment, the thickness of implant layer 26 may be in the range of 10-100 nanometers. In an alternate embodiment, the thickness of implant layer 26 may be approximately 50 nanometers.

Referring now to FIG. 7, an anneal is performed in order to drive the nitrogen from implant layer 26 into gate dielectric 14 and to the interfacial region between gate dielectric 14 and implant layer 26. In another embodiment, the anneal is performed to drive the nitrogen from implant layer 26 to the interfacial region between the gate dielectric 14 and the semiconductor substrate 12. In one embodiment, the anneal temperature used is within the range of 250-1000 degrees Celsius. In an alternate embodiment, the anneal temperature used is within the range of 400-800 degrees Celsius. In some embodiments, the anneal temperature used is approximately 500 degrees Celsius. In some embodiments, the anneals could be Rapid Thermal Anneal (RTP), UV (ultra-violet) anneal, and laser anneal. The method for forming device 10 may now proceed to FIG. 4, where implant layer 26 is either a portion of gate electrode 20 or is removed as a sacrificial layer.

Although the invention has been described with respect to specific conductivity types or polarity of potentials, skilled artisans appreciated that conductivity types and polarities of potentials may be reversed.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method of forming a semiconductor device, the method comprising:
providing a semiconductor substrate;
forming a gate dielectric over the semiconductor substrate;
exposing the gate dielectric to a plasma comprising a halogen;
incorporating the halogen into the gate dielectric;
forming a gate electrode over the gate dielectric; and
forming current electrode regions adjacent the gate electrode.

2. The method of claim 1, wherein the exposing the gate dielectric to the plasma comprising the halogen comprises exposing the gate dielectric to a plasma comprising fluorine.

3. The method of claim 1, wherein at least a portion of the forming the gate dielectric occurs concurrently with the exposing the gate dielectric to the plasma comprising the halogen.

4. The method of claim 1, wherein the method of forming the gate dielectric comprises forming a dielectric comprising silicon and oxygen.

5. The method of claim 1, wherein the method of forming the gate dielectric comprises forming a dielectric comprising a metal.

6. The method of claim 1, further comprising:
exposing the gate dielectric to nitrogen; and
incorporating the nitrogen into the gate dielectric.

7. The method of claim 6, wherein the exposing the gate dielectric to nitrogen occurs after the exposing the gate dielectric to the plasma comprising the halogen.

8. The method of claim 6, wherein the exposing the gate dielectric to nitrogen occurs before the exposing the gate dielectric to the plasma comprising the halogen.

9. The method of claim 6, wherein the exposing the gate dielectric to nitrogen comprises exposing the gate dielectric to a plasma comprising nitrogen.

10. The method of claim 9, wherein at least a portion of the exposing the gate dielectric to a plasma comprising nitrogen occurs concurrently with at least a portion of the exposing the gate dielectric to the plasma comprising the halogen.

11. A method for forming a semiconductor device, the method comprising:
providing a semiconductor substrate;
forming a gate dielectric over the semiconductor substrate;
incorporating a halogen into the gate dielectric;
incorporating nitrogen into the gate dielectric;
forming a gate electrode over the gate dielectric; and
forming current electrode regions adjacent the gate electrode.

12. The method of claim 11, wherein the incorporating the halogen into the gate dielectric comprises incorporating fluorine into the gate dielectric.

13. The method of claim 12, wherein the incorporating the halogen into the gate dielectric comprises exposing the gate dielectric to a plasma including fluorine.

14. The method of claim 11, wherein the incorporating nitrogen into the gate dielectric comprises exposing the gate dielectric to a plasma including nitrogen.

15. The method of claim 11, wherein the incorporating nitrogen into the gate dielectric comprises annealing the gate dielectric in an environment including nitrogen.

16. The method of claim 11, wherein at least a portion of the forming the gate dielectric occurs concurrently with incorporating the halogen into the gate dielectric.

17. The method of claim 11, wherein the incorporating the halogen into the gate dielectric occurs before the incorporating nitrogen into the gate dielectric.

18. The method of claim 11, wherein at least a portion of the incorporating the halogen into the gate dielectric occurs concurrently with at least a portion of the incorporating nitrogen into the gate dielectric.

19. The method of claim 11, wherein:
the forming the gate electrode is formed before the exposing the gate dielectric to nitrogen; and
the incorporating nitrogen into the gate dielectric comprises:
implanting the nitrogen into the gate electrode; and
diffusing the nitrogen from the gate electrode to the gate dielectric.

20. A semiconductor device comprising:
a semiconductor substrate;
a gate dielectric over the semiconductor substrate, wherein the gate dielectric comprises a halogen and nitrogen;
a gate electrode over the gate dielectric; and
current electrode regions adjacent the gate electrode.
